(19) United States
(12) Patent Application Publication
(10) Pub. No.: US 2018/0291499 A1
(43) Pub. Date: Oct. 11, 2018

(54) METHOD FOR MANUFACTURING COATED SUBSTRATES, COATED SUBSTRATES, USE THEREOF, AND SYSTEMS FOR MANUFACTURING COATED SUBSTRATES

(71) Applicant: HEC High End Coating GmbH, Allendorf (DE)

(72) Inventor: Matthias Koch, Bromskirchen (DE)

(21) Appl. No.: 15/744,573

(22) PCT Filed: Jul. 13, 2016
(86) PCT No.: PCT/EP2016/066592

§ 371 Date: Jun. 12, 2018

(30) Foreign Application Priority Data
Jul. 13, 2015 (EP) 15176519.5

(51) Int. Cl. C23C 14/20; C09D 183/04; C09D 183/08; C09D 5/00; B05D 1/00; B05D 7/02; C23C 14/16; C23C 16/50; C23C 16/06

(52) U.S. Cl. CPC C23C 14/20; C09D 183/04; C09D 183/08; C09D 5/002; C23C 16/06; B05D 7/02; C23C 14/16; C23C 16/50; B05D 1/62

(57) ABSTRACT

A method for manufacturing a coated non-metal substrate, in particular a plastic substrate, or manufacturing a coated metal substrate, involves applying at least one metal layer using an application system, treating the metal layer with at least one organosilicon compound, in particular using plasma polymerization, such that a polysiloxane layer is formed, plasma processing using a plasma generator and/or corona treatment of the polysiloxane layer, and applying an overcoat, in particular a transparent one, to the treated polysiloxane layer. Further disclosed is a non-metal substrate or a metal substrate that is obtained according to the disclosed method, as well as an application system for applying a metal layer and a method of using the disclosed substrates.

### BACKGROUND

### Technical Field

The present disclosure relates to methods for manufacturing coated substrates, coated substrates obtainable by these methods, and the use of these coated substrates. The present disclosure also relates to systems for manufacturing coated substrates.

### Description of the Related Art

Metallic and non-metallic components are frequently coated in order to produce a smooth and/or shining surface. As a rule, this involves multilayer coating systems. As well as the desire of obtaining a surface with a high-quality attractive appearance, the intention with such coating systems is regularly also to achieve significant corrosion protection. Not unusually, long-term corrosion protection is brought to nothing by mechanical damage. In many cases, even very slight mechanical damage causes corrosion on coated surfaces. As well as discoloration, this can also result in infiltration phenomena. Not unusually, this in turn leads to the flaking away of areas of coating. There has been no lack of experiments aimed at rendering coated shining surfaces resistant to corrosion. DE 123 765 A1, for example, describes a method for producing a corrosion protection layer on a metallic surface, in which a sol based on silicon compounds, an aminoalkyl-functionalized alkoxysilane or a conversion product of the two aforesaid components is used.

According to DE 38 33 119 C2, a corrosion-protected chromatized metal surface which adheres very well to a substrate is obtained by an electrodeposition coating being deposited directly onto the chromating layer, without intermediate drying.

Corrosion protection coatings for metal substrates nevertheless still exhibit a substantial potential for improvement with regard to adherence and corrosion protection, in particular with mass-produced products, in particular those with complex geometries.

There is accordingly a need to provide coated substrates which are no longer impaired by the disadvantages of the prior art, and which, in particular with regard to mass production, provide coated products with improved corrosion protection and/or very good adherence properties. It is also intended to provide such coated products which do not immediately exhibit infiltration phenomena in the event of mechanical surface damage, in particular not associated with the flaking away of layers. There further is a need to provide coated substrates which, even with a complex geometry, present a coating result of uniformly high quality over the entire component, including the areas along the length of edges.

### DETAILED DESCRIPTION

Accordingly, in at least one embodiment of the present disclosure, a method has been found for manufacturing a coated non-metallic substrate, in some cases a plastic substrate, comprising:

a) providing a non-metallic substrate, in some cases a plastic substrate, with at least one surface which is capable of being coated at least in part areas,

b) providing an application system for the application of a metal layer, in some cases a vacuum vapor deposition system or sputtering system,

c) providing at least one plasma generator and/or at least one corona system, in some cases within the application system for the application of a metal layer, such as the vacuum vapor deposition system or sputtering system, or as a component thereof,

d) as appropriate, providing plasma treatment with the plasma generator and/or corona treatment of the non-metallic substrate, in some cases plastic substrate, or of the coatable surface of the non-metallic substrate, in some cases plastic substrate,

e) as appropriate, treating the non-metallic substrate, in some cases plastic substrate, obtained according to step a) or d), or of the coatable surface of the non-metallic substrate, in some cases plastic substrate, with at least one organosilicon compound, in some cases by way of plasma polymerization, thus forming a polysiloxane layer,

f) as appropriate, providing plasma treatment with the plasma generator and/or corona treatment of the polysiloxane layer in accordance with step e),

g) as appropriate, applying at least one primer layer onto the non-metallic substrate, in some cases plastic substrate, or onto the coatable surface of the non-metallic substrate, in some cases plastic substrate, in accordance with step a) or d), or onto the polysiloxane layer in accordance with step e) or f),

h) as appropriate, providing plasma treatment with the plasma generator and/or corona treatment of the primer layer in accordance with step g),

i) as appropriate, treating the primer layer obtained according to step g) or h) with least one organosilicon compound, in some cases by way of plasma polymerization, thus forming a polysiloxane layer,

j) as appropriate, providing plasma treatment with the plasma generator and/or corona treatment of the polysiloxane layer in accordance with step i),

k) applying at least one metal layer, containing or consisting of a first metal, selected from the group consisting of aluminum, silver, gold, lead, vanadium, manganese, magnesium, iron, cobalt, nickel, copper, chromium, palladium, molybdenum, tungsten, platinum, titanium, zirconium and zinc, in some cases aluminum, or containing or consisting of a first metal alloy, selected from the group consisting of brass, bronze, steel, in some cases special or stainless steel, alloys of aluminum, magnesium and titanium, with the application system, in some cases by way of vapor deposition and/or sputtering technology, onto the non-metallic substrate, in some cases plastic substrate, or onto the coatable surface of the non-metallic substrate, in some cases plastic substrate, in accordance with step a) or d), or onto the polysiloxane layer in accordance with step e) or f), or onto the primer layer in accordance with step g) or h), or onto the polysiloxane layer in accordance with step i) or j),

l) as appropriate, providing plasma treatment with the plasma generator and/or corona treatment of the metal layer in accordance with step k),

m) treating the metal layer obtained according to step k) or l) with at least one organosilicon compound, in some cases by way of plasma polymerization, thus forming a polysiloxane layer,

n) providing plasma treatment with the plasma generator and/or corona treatment of the polysiloxane layer in accordance with step m), and

o) applying an overcoat, in some cases a transparent overcoat, onto the treated polysiloxane layer in accordance with step n).

The present disclosure also provide, in some cases, a method comprising the steps of:

a) providing a non-metallic substrate, in some cases plastic substrate, with at least one surface which is capable of being coated at least in part areas,

b) providing an application system for the application of a metal layer, in some cases a vacuum vapor deposition system or sputtering system,

c) providing at least one plasma generator and/or at least one corona system, in some cases within the application system for the application of a metal layer, such as the vacuum vapor deposition system or sputtering system, or as a component thereof,

d) as appropriate, providing plasma treatment with the plasma generator and/or corona treatment of the non-metallic substrate, in some cases plastic substrate, or of the coatable surface of the non-metallic substrate, in some cases plastic substrate,

e) as appropriate, treating the non-metallic substrate, in some cases plastic substrate, obtained according to step a) or d), or of the coatable surface of the non-metallic substrate, in some cases plastic substrate, with at least one organosilicon compound, in some cases by way of plasma polymerization, thus forming a polysiloxane layer,

f) as appropriate, providing plasma treatment with the plasma generator and/or corona treatment of the polysiloxane layer in accordance with step e),

g) applying at least one primer layer onto the non-metallic substrate, in some cases plastic substrate, or onto the coatable surface of the non-metallic substrate, in some cases plastic substrate, in accordance with step a) or d), or onto the polysiloxane layer in accordance with step e) or f),

h) providing plasma treatment with the plasma generator and/or corona treatment of the primer layer in accordance with step g),

i) as appropriate, treating the primer layer obtained according to step g) or h) with at least one organosilicon compound, in some cases by way of plasma polymerization, thus forming a polysiloxane layer,

k) applying at least one metal layer, containing or consisting of a first metal, selected from the group consisting of aluminum, silver, gold, lead, vanadium, manganese, magnesium, iron, cobalt, nickel, copper, chromium, palladium, molybdenum, tungsten, platinum, titanium, zirconium and zinc, in some cases aluminum, or containing or consisting of a first metal alloy selected from the group consisting of brass, bronze, steel, in some cases special or stainless steel, alloys of aluminum, magnesium and titanium, with the application system, in some cases by way of vapor deposition and/or sputtering technology, onto the primer layer in accordance with step g) or h), or onto the polysiloxane layer in accordance with step i),

m) treating the metal layer obtained according to step k) with at least one organosilicon compound, in some cases by way of plasma polymerization, thus forming a polysiloxane layer,

n) providing plasma treatment with the plasma generator and/or corona treatment of the polysiloxane layer in accordance with step m), and

o) applying an overcoat, in some cases a transparent overcoat, onto the treated polysiloxane layer in accordance with step n).

In this method variant, steps d), e) and f) are only optional. In individual cases, they can contribute to improved adherence and increased corrosion protection. The same applies to the optional step i). It has shown for some applications that it is of advantage if a polysiloxane layer is present on both sides of the metal layer, in some cases a plasma-generated polysiloxane layer, which in a suitable embodiment has in each case been subjected to a plasma treatment and/or a corona treatment, in some cases plasma treatment.

The method variant described heretofore, comprising the application of a primer layer, is particularly well-suited for non-metallic substrates, in some cases plastic substrates, with a surface which exhibits uneven areas or which is of inferior quality.

For many applications, however, a method has proved to be entirely adequate in achieving the objectives of the present disclosure, in which, in addition to the method steps a), b) and c), also comprises the method steps d), e), f), k), m), n) and o), or k), m), n) and o) respectively as obligatory method steps, wherein, in a suitable embodiment, in each case prior to step k) of the application of the metal layer, provision can be made for the application of a polysiloxane layer (step i)), in some cases a plasma-generated polysiloxane layer. The method variant described heretofore can be applied, in some cases, with faultless non-metallic substrates, in some cases plastic substrates with faultless smooth surfaces.

Furthermore, in a further development of the method according to the present disclosure for manufacturing non-metallic substrates, in some cases of plastic substrates, the step sequence d), e), f), g), k), m), n) and o), or g), k), m), n) and o) respectively can be used, i.e., omitting the treatment or activation of the primer layer with a plasma (step h)). Likewise, step h) can also be applied here. Here too, it may be of advantage to apply a polysiloxane layer, in some cases a plasma-generated polysiloxane layer (step i)) before step k) of the application of the metal layer. Furthermore, in one embodiment, in addition to the method steps a), b) and c), it is also possible to make use of the sequence of method steps d), e), f), g), h), k), m), n) and o), or the method steps d), i), j), k), m), n) and o).

In a suitable embodiment, in some cases as specified heretofore, the layer onto which the metal layer is applied in accordance with step k) is subjected to a plasma treatment with the plasma generator and/or a corona treatment (e.g., steps j), f) or d)) before step k).

It has proved to be of advantage for the method steps referred to heretofore to be applied essentially immediately after one another. This means, in some cases, that an extended dwell period after the plasma treatment steps should be avoided. Rather, it is of advantage if the subsequent method step follows directly. It has also shown that it is not necessary for further method steps to be interspersed between the method steps referred to heretofore.

In one embodiment, it has also proved to be advantageous, in some cases with regard to good adherence and corrosion protection, if the non-metallic substrate, in some cases the plastic substrate, is subjected to a plasma treatment and/or corona treatment, in some cases plasma treatment (step d)).

Suitable non-metallic substrates include glass, ceramics, fiber composite materials, carbon materials, plastic, or wood. A method according to the disclosure described here is particularly well-suited for coating plastic substrates for the purpose of obtaining durable high-gloss products. Suitable plastic substrates comprise or consist of, for example, PVC, polyurethanes, polyacrylates, polyesters, e.g., PBT and PET, polyolefins, in some cases polypropylene, polycarbonates, polyamides, polyphenylene ethers, polystyrene, styrene (co)polymers, such as ABS, SAN, ASA or MABS, polyoxyalkylenes, e.g., POM, Teflon™ and polymer blends, in some cases ABS/PPE, ASA/PPE, SAN/PPE and/or ABS/PC blends.

The present disclosure further provides a method for manufacturing a coated metal substrate, comprising:

A) providing a metal substrate with at least one surface which is capable of being coated at least in part areas,

B) providing an application system for the application of a metal layer, in some cases a vacuum vapor deposition system,

C) providing at least one plasma generator and/or at least one corona system, in some cases within the application system for the application of a metal layer, such as the vacuum vapor deposition system or sputtering system, or as a component thereof,

D) as appropriate, cleaning of the metal substrate or of the coatable surface of the metal substrate,

E) as appropriate, applying at least one metal layer, containing or consisting of a second metal, selected from the group consisting of titanium, hafnium and zirconium, in some cases zirconium, or of a second metal alloy, selected from the group consisting of alloys of titanium, hafnium and zirconium, with the application system, in some cases by way of vapor deposition and/or sputtering technology, onto the metal substrate or the coatable surface of the metal substrate in accordance with step A) or D),

F) as appropriate, providing plasma treatment with the plasma generator and/or corona treatment of the metal substrate or of the coatable surface of the metal substrate in accordance with step A) or D), or of the metal layer in accordance with step E),

G) as appropriate, treating the metal substrate obtained according to step A) or D), or treating the coatable surface of the metal substrate obtained according to step A) or D) or of the metal layer obtained according to step E) or F) with at least one organosilicon compound, in some cases by way of plasma polymerization, thus forming a polysiloxane layer,

H) as appropriate, providing plasma treatment with the plasma generator and/or corona treatment of the polysiloxane layer in accordance with step G),

I) as appropriate, applying a conversion layer onto the metal substrate or the coatable surface of the metal substrate in accordance with step A) or D), or onto the metal layer in accordance with step E) or F), or onto the polysiloxane layer in accordance with step G) or H),

J) as appropriate, providing plasma treatment with the plasma generator and/or corona treatment of the conversion layer in accordance with step I),

K) as appropriate, treating the conversion layer obtained according to step I) or J) with at least one organosilicon compound, in some cases by way of plasma polymerization, thus forming a polysiloxane layer,

L) as appropriate, providing plasma treatment with the plasma generator and/or corona treatment of the treated polysiloxane layer obtained according to step K),

M) as appropriate, applying at least one primer layer onto the metal substrate or the coatable surface of the metal substrate in accordance with step A) or D), or onto the metal layer in accordance with step E) or F), or onto the polysiloxane layer in accordance with step G) or H), or onto the conversion layer in accordance with step I) or J), or onto the polysiloxane layer in accordance with step K) or L),

N) as appropriate, providing plasma treatment with the plasma generator and/or corona treatment of the primer layer in accordance with step M),

O) as appropriate, treating the primer layer obtained according to step M) or N) with at least one organosilicon compound, in some cases by way of plasma polymerization, thus forming a polysiloxane layer,

P) as appropriate, providing plasma treatment with the plasma generator and/or corona treatment of the treated polysiloxane layer obtained according to step O),

Q) applying at least one metal layer, containing or consisting of a first metal, selected from the group consisting of aluminum, silver, gold, lead, vanadium, manganese, magnesium, iron, cobalt, molybdenum, tungsten, nickel, copper, chromium, palladium, platinum, titanium, zirconium and zinc, in some cases aluminum, or containing or consisting of a first metal alloy, selected from the group consisting of brass, bronze, steel, in some cases special steel or stainless steel, alloys of aluminum, magnesium and titanium, with the application system, in some cases by way of vapor deposition and/or sputtering technology, onto the metal substrate or the coatable surface of the metal substrate in accordance with step A) or D) or F), or onto the polysiloxane layer in accordance with step G) or H), or onto the conversion layer in accordance with step I) or J), or onto the polysiloxane layer in accordance with step K) or L), or onto the primer layer in accordance with step M) or N), or onto the polysiloxane layer in accordance with step O) or P),

R) as appropriate, providing plasma treatment with the plasma generator and/or corona treatment of the metal layer in accordance with step Q),

S) treating the metal layer obtained according to step Q) or R) with at least one organosilicon compound, in some cases by way of plasma polymerization, thus forming a polysiloxane layer,

T) providing plasma treatment with the plasma generator and/or corona treatment of the polysiloxane layer in accordance with step S), and

U) applying an overcoat, in some cases a transparent overcoat, onto the treated polysiloxane layer in accordance with step T).

The present disclosure also provides, in some cases, a method comprising the steps of:

A) providing a metal substrate with at least one surface which is capable of being coated at least in part areas,

B) providing an application system for the application of a metal layer, in some cases a vacuum vapor deposition system,

C) providing at least one plasma generator and/or at least one corona system, in some cases within the application system for the application of a metal layer, such as the vacuum vapor deposition system or sputtering system, or as a part thereof,

D) cleaning of the metal substrate or of the coated surface of the metal substrate,

M) applying at least one primer layer onto the metal substrate or the coatable surface of the metal substrate in accordance with step D),

Q) applying at least one metal layer, containing or consisting of a first metal, selected from the group consisting of aluminum, silver, gold, lead, vanadium, manganese, magnesium, iron, cobalt, molybdenum, tungsten, nickel, copper, chromium, palladium, platinum, titanium, zirconium and zinc, in some cases aluminum, or containing or consisting of a first metal alloy, selected from the group consisting of brass, bronze, steel, in some cases special steel or stainless steel, alloys of aluminum, magnesium and titanium, with the application system, in some cases by way of vapor deposition and/or sputtering technology, onto the primer layer in accordance with step M),

S) treating the metal layer obtained according to step Q) with at least one organosilicon compound, in some cases by way of plasma polymerization, thus forming a polysiloxane layer,

T) providing plasma treatment with the plasma generator and/or corona treatment of the polysiloxane layer in accordance with step S), and

U) applying an overcoat, in some cases a transparent overcoat, onto the polysiloxane layer in accordance with step T).

It has shown for some applications that it is also of advantage in the manufacture of coated metal substrates if a polysiloxane layer, such as a plasma-polymerized polysiloxane layer, is present on both sides of the metal layer, i.e., method step O) is interspersed, in some cases with subsequent plasma treatment and/or corona treatment, and advantageously with plasma treatment. It is therefore possible, for example, for the method variant described heretofore also to be provided with step O).

A suitable corrosion protection is also obtained with the metal substrate which is obtainable in accordance with the method according to the present disclosure, if at least one metal layer is applied onto the metal substrate cleaned in accordance with step D), or onto the cleaned coatable surface of the metal substrate, this metal layer containing or consisting of a second metal, selected from the group consisting of titanium, hafnium and zirconium, in some cases zirconium, or of a second metal alloy, selected from the group consisting of alloys of titanium, hafnium and zirconium, with the application system, in some cases by way of vapor deposition and/or sputtering technology (step E)). It is advantageous if this metal layer is subsequently subjected to a plasma treatment step (step F)).

Provision can further be made for the method steps D), G), H), M), Q), S), T) and U), or D), G), H), M), O), Q), S), T) and U) to be used as obligatory method steps in addition to the method steps A) to C).

Moreover, the method according to the disclosure provides very satisfactory results with regard to adherence, gloss and corrosion resistance while maintaining the sequence of the obligatory method steps D), E), G), H), M), Q), S), T) and U), or maintaining the sequence of the obligatory method steps D), E), G), H), M), O), Q), S), T) and U), or maintaining the sequence of the obligatory method steps D), M), N), Q), S), T) and U), or maintaining the sequence of the obligatory method steps D), M), N), O), Q), S), T) and U), or maintaining the sequence of the obligatory method steps D), G), H), Q), S), T) and U), or maintaining the sequence of the obligatory method steps D), G), H), O), Q), S), T) and U), and in some cases also if the method steps follow one another immediately in the sequence indicated.

The following method sequence is also very suitable, in which, in addition to the method steps A) to C), use is made of the sequence D), I), K), L), Q), S), T) and U), or of the sequence D), F), Q), S), T) and U), or of the sequence D), G), H), Q), S), T) and U).

In another suitable embodiment, the layer onto which the metal layer is applied in accordance with step Q) is subjected to a plasma treatment with the plasma generator and/or a corona treatment (for example, steps P), N), L), J), H), F) or D)) before the step Q). This also applies, in some cases, to the polysiloxane layer.

It has also proved advantageous, in some cases in relation to good adherence and corrosion protection, if the metallic substrate, in some cases the cleaned metallic substrate, is subjected to a plasma treatment and/or a corona treatment, in some cases a plasma treatment (step F)).

In many cases, it has therefore proved advantageous if a polysiloxane layer is applied, this layer is then subjected to a plasma treatment and/or a corona treatment, in some cases a plasma treatment. The same applies to the application of a primer layer. It has also proved advantageous here if the primer layer obtained is initially subjected to a plasma treatment and/or a corona treatment, in some cases a plasma treatment.

It has accordingly also proved advantageous in the manufacture of coated metal substrates according to the inventive method if the method steps referred to heretofore are carried out essentially immediately following one another. This means, in some cases, that an extended dwell period after the plasma treatment steps should be avoided. Rather, it is of advantage if the subsequent method step follows directly. It has also shown that it is not necessary for further method steps to be interspersed between the method steps referred to heretofore.

For the metal substrates, recourse can be made to metals and metal alloys, where in some cases suitable metal substrates can be selected from the group consisting of aluminum, aluminum alloys, iron, iron alloys, in some cases steel or special or stainless steel, copper, copper alloys, titanium, titanium alloys, zinc, zinc alloys, nickel, nickel alloys, molybdenum, molybdenum alloys, magnesium, magnesium alloys, lead, lead alloys, tungsten, tungsten alloys, manganese, manganese alloys, brass, bronze, die-cast nickel, die-cast zinc and die-cast aluminum, or any mixtures thereof.

Suitable methods for cleaning metal substrates are known to the person skilled in the art. Such cleaning methods (step D)) comprise degreasing, pickling, phosphating, in some cases iron phosphating and/or zinc phosphating, polishing, grinding, in some cases finish grinding, and/or treating with dry ice. These methods can be used both individually as well as in any desired combination. For many applications it has proved sufficient for the metal substrates to be cleaned by treating them with dry ice. During cleaning with dry ice, in general, dry ice particles in the form of pellets or in the form of crystals, which have been shaved off an appropriate block of dry ice, are accelerated with the aid of compressed air and directed onto the metal surface which is to be cleaned. The cleaning effect is assumed to be attributable to thermal, kinetic, and phase transformation effects. Devices and methods for the cleaning of metal surfaces with dry ice can be found, for example, in DE 195 44 906 A1 and EP 2 886 250.

The surface of metal substrates can be degreased, for example, with alkaline or acidic reagents. Commercial degreasing steps are also known under the terms of hot alkaline cleaning or pickling cleaning. As an alternative, a metal surface can be degreased by anode effect in an electrolytic degreasing bath.

For a number of variant embodiments, it is advantageous for the metal substrate surface, in some cases the degreased metal substrate surface, to be subjected to at least one pickling step. For pickling the metal substrate surface, use is made, for example, of an acidic flushing bath. A suitable pickling solution is provided, for example, by dilute hydrochloric acid (1:10 vol/vol). As a result of pickling, as a rule, a metal surface is obtained which is essentially free of oxides. Like the degreasing step, the pickling step is, in general, concluded by a flushing step. If the metal substrate surface is polished and/or ground or finish-ground, it is frequently possible to do without the degreasing step and/or pickling step. With this form of surface treatment, sufficient material is usually removed from this surface for any contamination or other constituents adhering to the surface to be removed together with it. If the surface is polished or ground, it is frequently also possible to omit the application of a first and, if appropriate, second primer layer. In most cases, polishing or grinding already provides a surface which is sufficiently flat or smooth for further smoothing by the application of a primer layer to be no longer necessary. It may, however, be recommendable for a first and possibly also a second primer step to be added if the metal substrate has a considerable number of angles and corners, which cannot simply be adequately polished or ground without further ado.

Following or instead of the degreasing step, the metallic substrate surface can be phosphated and/or passivated. This is suitable, for example in some cases, with substrates made of or containing aluminum.

In a further embodiment of the method according to the present disclosure for manufacturing coated metal substrates, substrates with very particular corrosion resistance can be attained if, in the step of the application of the metal layer, a first metal, in some cases aluminum, or a first metal alloy, in some cases an aluminum alloy, is co-vapor deposited in the application system for the application of a metal layer, in some cases the vacuum vapor deposition system or the sputtering system, overlapping in time with a second metal, which is different from the first metal, in some cases selected from the group consisting of titanium, zirconium and hafnium, in some cases zirconium, or with a second metal alloy, in some cases a zirconium alloy, which is different from the first metal alloy. This takes place, for example, in the form that metal pellets or rods of the first metal or the first metal alloy are introduced into an appropriate first reception container, in some cases a first boat element or a first helical shaft, and the metal pellets or rods of the second metal or the second metal alloy are introduced into an appropriate second reception container, second boat element or a second helical shaft, and that the first and the second reception container are heated in such a way that the melting points of the first and second metals or of the first and second metal alloys or of the first metal and second metal alloy or of the first metal alloy and second metal are attained and/or maintained essentially simultaneously or within an overlapping period of time.

Suitable aqueous conversion systems, with the aid of which conversion layers are obtained, are familiar to the person skilled in the art. By way of example, reference may be made to the disclosures of U.S. Pat. No. 2,825,697 and U.S. Pat. No. 2,928,763.

For the application of the primer layer, generally known methods are at the disposal of a person skilled in the art. Examples which may be referred to include the wet-coating process, the powder-coating process, or application by way of UV-curing coating systems. Accordingly, in a suitable embodiment, the primer layer may be based in some cases on UV-curing powdery polyester resin compounds or to epoxy/polyester powder. It is, of course, also possible, to carry out a mechanical smoothing of the metal substrate surface, for example by grinding and/or polishing or finish-grinding, before the application of a primer layer, as described heretofore.

Suitable organosilicon compounds are known to the person skilled in art. In one suitable embodiment, recourse is made for this purpose to at least one amino-containing silane, in some cases aminopropyltriethoxysilane, hexamethyldisiloxane, tetramethyldisiloxane, or any mixtures thereof. It is also suitable that use is made of hexamethyldisiloxane and tetramethyldisiloxane, wherein hexamethyldisiloxane is regularly well-suited.

Suitable organosilicon compounds likewise comprise, as monomer or as co-monomer structural units, compounds of the following formula (I):

X—R₁—Si(R₂)₃₋ₘ(R₃)ₘ (I)

wherein the substituents and indices have the following meaning:

m is 0, 1, 2 or 3, in some cases 2 or 3,

R1 is a C1 to C10 hydrocarbon residue, in some cases a C1 to C10 hydrocarbon chain, which may be interrupted by oxygen or nitrogen, such as methyl, ethyl, or i- or n-propyl, in some cases i- or n-propyl,

R2 are identical or different hydrolysable groups, in some cases alkoxy groups, such as methoxy, ethoxy, n-propoxy, i-propoxy, n-butoxy, i-butoxy or t-butoxy, such as methoxy or ethoxy,

R3 are identical or different C1 to C5 alkyl groups, such as methyl, ethyl or i- or n-propyl, in some cases i- or n-propyl, and

X is a functional polymerisable group, in some cases an unsaturated organic residue in the co position, such as an unsaturated alkenyl group in the co position with 1 to 10, in a suitable embodiment 2 to 4 C atoms, or an unsaturated carboxylic acid residue in the co position of carboxylic acids with up to 4 carbon atoms, and alcohols with up to 6 carbon atoms.

Suitable residues X comprise, for example, vinyl, alkylvinyl, in some cases methyl, ethyl or propyl vinyl, (meth)acryloxyalkyl, in some cases (meth)acryloxymethyl, (meth)acryloxyethylene or (meth)acryloxypropyl, in some cases (meth)acryloxypropyl.

In a further development of the method according to the present disclosure, provision is made for a first organosilicon compound to be delivered to the application system, in some cases vacuum chamber, via a feed line from a first container located outside the application system for the application of a metal layer, in some cases outside the vacuum chamber of the vacuum vapor deposition system, and for a second organosilicon compound, which is different from the first organosilicon compound, to be delivered to the application system, in some cases vacuum chamber, via a feed line from a second container located outside the application system for the application of a metal layer, in some cases outside the vacuum chamber of the vacuum vapor deposition system. As an alternative, the same organosilicon compound can be present in the first and second container. In some cases, it is possible, that, if the same organosilicon compounds are used, one of these organosilicon compounds can be present mixed with a further, different organosilicon compound and/or with a coloring agent, such as a dye. Accordingly, the methods according to the present disclosure are also characterized in that, together with the at least one organosilicon compound, in some cases for the plasma polymerization, at least one coloring agent, such as a dye, is introduced into the application system for the application of a metal layer, in some cases in the form of a mixture. This latter method variant, comprising the use of a coloring agent, naturally is also successful if only one container is used.

Accordingly, the present disclosure likewise relates to an application system for the application of a metal layer, comprising at least one first container, located in some cases outside the application system for the application of a metal layer, in some cases outside the vacuum chamber of the vacuum vapor deposition system, for holding a first organosilicon compound, with a feed line to the application system, in some cases to the vacuum chamber, and at least one second container, located in some cases outside the application system for the application of a metal layer, in some cases outside the vacuum chamber of the vacuum vapor deposition system, for holding a second organosilicon compound, with a feed line to the application system, in some cases to the vacuum chamber.

Good adherence without restrictions with regard to corrosion resistance is also achieved in some cases due to the fact that the step of treatment with at least one organosilicon compound, such as hexamethyldisiloxane, in some cases by way of plasma polymerization, thus forming a polysiloxane layer, takes place in the presence of at least one reactive gas, such as oxygen, nitrogen, carbon dioxide, hydrogen, carbon monoxide, hydrogen peroxide gas, water vapor, ozone and/or air, in some cases in the presence of oxygen or air. By way of the integration of reactive gases, in some cases air or oxygen, into the polymerization process, in some cases plasma-generated, harder polysiloxane layers are obtained than with the conventional manufacture of such polysiloxane layers, without the concomitant use of the reactive gases described. These harder polysiloxane layers are also characterized by greater diffusion consistency. In this context, in a suitable embodiment, provision can be made for the at least one organosilicon compound, in some cases hexamethyldisiloxane, and the at least one reactive gas, in some cases oxygen or air, to be used as a mixture for the treatment step. The embodiment described heretofore of the concomitant use of reactive gases in the production, in some cases plasma-generated, of the polysiloxane layer, is used suitably in at least one step of the treatment with at least one organosilicon compound, in some cases by way of plasma polymerization, thus forming a polysiloxane layer, or also with each step for the production of a polysiloxane layer. In a suitable embodiment, this method variant is used in the manufacture of coated non-metallic substrates, in some cases of plastic substrates, in method step m) and in the manufacture of coated metallic substrates in method step S). In the method steps following those referred to, namely method steps n) and T) respectively, the plasma treatment is in some cases carried out with the aid of a plasma gas, formed from an inert gas, such as argon, and oxygen or air or nitrogen, in some cases oxygen, or with the aid of a plasma gas formed from oxygen, air or nitrogen. This procedure again contributes to a better adherence of the total system, including the overcoat.

For the step of the plasma treatment with the plasma generator, there are in principle a number of method variants available for selection. According to a first variant, the plasma can be formed using at least one inert gas, in some cases argon. As an alternative, for the generation of a suitable plasma, recourse can also be made to mixtures of at least one inert gas, in some cases argon, and a reactive gas such as oxygen, nitrogen, carbon dioxide, hydrogen, carbon monoxide, hydrogen peroxide gas, water vapor, ozone and/or air. Use is made here, in some cases, of oxygen and nitrogen, e.g., oxygen. Finally, it is also possible to exclude inert gases and to use exclusively reactive gases, such as oxygen, nitrogen, hydrogen, carbon dioxide, carbon monoxide, hydrogen peroxide gas, water vapor, ozone and/or air for the production of the plasma. In this situation, recourse is made preferable to oxygen. With the aid of a plasma treatment with the plasma generator, the surface to be coated of the substrate is activated. In a plasma process, an energy-rich plasma regularly takes effect on the surface of the shaped part such that active centers are formed on this surface. This can involve, for example, hydroxyl groups and/or carbonyl groups. In the same way, an activation of the surface of the substrate surface which is to be coated can be put into effect by flame treatment. In a suitable embodiment, a volatile silane or a compound containing titanium and aluminum can be added to a flame, such as a propane gas flame, which burns in an air atmosphere. Due to the flame application, the surface of the substrate, in some cases of a plastic substrate, can be changed in a similar manner as in the plasma process, thus forming hydroxyl groups, for example.

The methods according to the present disclosure provide a great advantage in that almost all method steps can be carried out in the application system for the application of a metal layer. As well as the application of metal layers, this also relates to the activation of surfaces by way of plasma treatment with the plasma generator, as well as to the application of the polysiloxane layer, in some cases by way of plasma polymerization. Only the cleaning step, the application of a primer layer, the application of a conversion layer, and the application of the overcoat are regularly carried out outside the application system referred to herein. Provision can therefore be made that the plasma treatment, in some cases each plasma treatment, is carried out with the plasma generator and/or the application, in some cases each application, of the metal layer, and/or the application, in some cases each application, of the polysiloxane layer is carried out within the application system for the application of a metal layer, in some cases in the vacuum vapor deposition system or in the sputtering system, and/or that the application of the primer layer and/or the application of the conversion layer and/or the application of the overcoat takes place outside the application system for the application of a metal layer, in some cases of the vacuum vapor deposition system or of the sputtering system.

For the overcoat, for example, recourse can also be made to water-dilutable coating compositions. The overcoat can be formed from polyacrylate resins, polyester resins, aminoplast resins, or polyurethane compounds. In some cases, in the methods according to the disclosure, such overcoats are applied as are based on a UV-curing coating material. Accordingly, a suited overcoat can be a UV-cured overcoat. The overcoat can be obtained, for example, by way of a clear lacquer or a transparent powder. The overcoat is in some cases applied by a wet-paint process or a powder coating process. The overcoat can accordingly be, for example, a single-component, two-component, or multi-component lacquer, wherein clear lacquers represent an advantageous embodiment. These clear lacquers can be, for example, chemically cross-linking two-component lacquers, single-component heat-curing lacquers, or UV-curing lacquers. In addition, 1K or 2K stoving lacquer may be used.

As a rule, the overcoat usually has a thickness in the range from 10 to 50 μm, in some cases in the range from 20 to 30 μm. Of inventive importance to the method according to the disclosure is the fact that the material forming the overcoat is applied onto a polysiloxane layer which has been previously activated by way of plasma treatment and/or corona treatment and which was in some cases obtained by a plasma polymerization, and suitably essentially without any time delay.

The plasma treatment with the plasma generator is sometimes also described by the term glowing.

For the application of the metal layers, recourse can be made, for example, to the technologies of Physical Vapor Deposition (PVD), Chemical Vapor Deposition (CVD), vapor deposition by way of an electron beam evaporator, vapor deposition by way of a resistance evaporator, induction vapor deposition, ARC evaporation, or cathode or anode atomization (sputter coating). Accordingly, application systems for the application of a metal layer in some cases include, for example, vacuum vapor deposition systems or sputtering systems. Suitable vacuum vapor deposition systems comprise PVD systems (Physical Vapor Deposition), CVD systems (Chemical Vapor Deposition), electron beam evaporators, resistance evaporators, induction evaporators, and ARC evaporators. Suitable sputtering systems comprise, for example, cathode atomizers and anode atomizers. As a person skilled in the art knows, a metal layer consists predominantly of metal. This does not entirely exclude additives, such as are used, for example, with stainless steel in the form of carbon. In some cases, the metal content of the metal layer in this situation is greater than 90% by weight, in some cases 95% by weight, and in some other cases ≥98% by weight.

In an advantageous embodiment, the metal layer is a vapor-deposited or sputter-applied metal layer, in some cases a PVD metal layer. In the PVD method, in general, resistance-heated metal helical shaft or metal boat element evaporators are used, wherein tungsten chutes of the most widely differing forms are suited. In the PVD method, in general, an evaporator is fitted with helical shafts which can be clamped onto evaporator rails which are insulated from one another. In some cases, a precisely determined quantity of metal to be deposited is introduced into each chute. After the PVD system has been closed and evacuated, the evaporation can be started by switching on the power supply, as a result of which the evaporation rails cause the chutes to be brought to a glow. The solid metal begins to melt, and thoroughly wets the chutes, which in most cases are twisted in form. By the further application of energy, the liquid metal is transformed into the gas phase, so that it can then be deposited on the substrate which is to be coated. By way of the quantity of metal transformed into the gas phase, and/or the duration of the coating phase, the thickness of the metal layer, and therefore also its appearance, can be specifically adjusted.

A further suitable method for depositing the metal layer onto the substrate is cathode atomization (sputtering). Here, a cathode is arranged in an evacuated container and connected to the negative pole of a current supply. The coating material which is to be atomized is arranged directly in front of the cathode, and the substrates which are to be coated are arranged opposite the coating material which is to be atomized. In addition, argon can be conveyed, as the process gas, through the container, which also comprises an anode which is connected to the positive pole of a current supply. Once the container has been pre-evacuated, the cathode and anode are connected to the current supply. Due to the specific and controlled admission of argon, the average free path length of the charge carriers is perceptibly reduced. Argon atoms are ionized in the electrical field between the cathode and the anode. The positively charged particles are accelerated with high energy towards the negatively charged cathode. On impinging, and due to particle impacts in the coating material, this material is transformed into the vapor phase, accelerates with high energy into the free space, and then condenses on the substrates which are to be coated. Sputtering allows for different metal layer thicknesses to be specifically adjusted.

The metal layers obtainable with the methods and systems described herein suitably have an average, in some cases absolute, thickness in the range from 1 nm to 150 nm, in some cases in the range from 5 nm to 120 nm. In a suitable embodiment of the coated substrate according to the present disclosure, the metal layer is adjusted, for example, with a thickness in the range from 60 nm to 120 nm, in some cases with a thickness in the range from 75 nm to 110 nm. With these thicknesses, the metal layers, in some cases the aluminum layer, cover the surface in an opaque manner, i.e., they are essentially not transparent or translucent. This allows for high-gloss layers to be obtained.

A coloring of the coating present on the non-metallic and metallic substrates can also be accomplished with the methods according to the present disclosure, if a coating material is used for the application of the overcoat which contains at least one coloring agent, e.g., at least one pigment and/or at least one dye. Glazes, which are known to persons skilled in the art, can also be used in order to color the overcoat, such as to obtain, for example, brass, titanium and gold color shades, or individual color shades such as red, blue, yellow, green, etc., or anodized color shades. For example, effect pigments can also be introduced into the overcoat, such as pearl gloss pigments, LCP (liquid crystal polymer) pigments or OV (optical variable) pigments.

The present disclosure further provides a non-metallic substrate, obtained or capable of being obtained by the method according to the present disclosure for coating non-metallic substrates, in some cases plastic substrates. The present disclosure also further provides a metal substrate, obtained or capable of being obtained by the method according to the present disclosure for coating metal substrates.

The present disclosure also provides an application system for the application of a metal layer, comprising or representing a vacuum vapor deposition system with a vacuum chamber, and at least one, in some cases a plurality of, first heatable reception units, in some cases trays, boat elements, or helical shafts, in each case operatively coupled with a first heating device or comprising or representing a first heating device, in each case configured and suitable for the reception of a first metal or a first metal alloy with a first melting point or melting range, and at least one, in some cases a plurality of, second heatable reception units, in some cases trays, boat elements, or helical shafts, in each case operatively coupled with a second heating device or comprising or representing a second heating device, in each case configured and suitable for the reception of a second metal or a second metal alloy with a second melting point or melting range, wherein the first melting point or the first melting range are different from the second melting point or second melting range, and, in addition, a control device for the adjustment of first and second temperatures in such a way that the first and the second metal or the first and second metal alloy evaporate essentially simultaneously or overlapping in time (co-evaporation).

Here, provision can be made in one embodiment variant that the application system for the application of a metal layer comprises at least one first container, located in some cases outside the vacuum chamber of the vacuum vapor deposition system, for receiving a first organosilicon compound, with a feed line to the vacuum chamber, and at least one second container, located in some cases outside the vacuum chamber of the vacuum vapor deposition system for receiving a second organosilicon compound, with a feed line to the vacuum chamber.

It has proved suitable for the application system according to the present disclosure for the application of a metal layer to be also equipped with at least one frame, in some cases arranged within the vacuum chamber, with a longitudinal orientation and with at least one support, in some cases in the form of a shaft, which is aligned essentially along the longitudinal orientation of the frame, designed and configured to receive at least one, in some cases a plurality of, non-metallic and/or metallic substrates, wherein the frame and/or the at least one support is/are capable of being rotated about an axis. Suitable frames which can be used with the application system according to the present disclosure can be found, for example, in EP 2 412 445 and DE 20 2007 016 072.

The non-metallic and metallic substrates which are obtainable with the method according to the present disclosure can be used, for example, as accessories for automobile manufacture, motorcycle manufacture, bicycle manufacture or shipbuilding, for rims, in some cases light metal alloy rims, wheels, in some cases light metal alloy wheels, or as a constituent part thereof, for sanitary installation objects, in some cases as a tap or mixer, or as a constituent part thereof, for automobile body internal or external components or as a constituent part thereof, for handles or handle components, in some cases door handles, or as a constituent part thereof, for profiles or frames, in some cases window frames, or as a constituent part thereof, for fittings systems or as a constituent part thereof, in some cases signs and door signs, for housings or as packing or as a constituent part thereof, for internal or external components of ships or as a constituent part thereof, for jewelry items or as a constituent part thereof, for high-quality structural components or as a constituent part thereof, for indoor or outdoor furniture items or for constituent parts thereof, for domestic appliances, in some cases coffee-making machines, or as a constituent part thereof, for internal or external components of aircraft or as a constituent part thereof, for internal or external components of buildings or as a constituent part thereof, for heating elements or pipes or as a constituent part thereof, for elevator components or as a constituent part thereof, for parts of electronic components or devices or as a constituent part thereof, for components of kitchen appliances, for example coffee-making machines, or as a part of communications components or devices, in some cases mobile telephones, or as a constituent part thereof.

The present disclosure is based on the surprising finding that, with the substrates obtainable with the methods according to the disclosure, a high-quality gloss coating is provided, which retains its gloss in the long term. In addition, it has surprisingly been found that the coated non-metallic and metallic substrates obtainable with the method according to the present disclosure are provided with excellent corrosion resistance. The coated substrates obtainable with the methods according to the disclosure are further characterized by very good adherence. Accordingly, these coated substrates exhibit outstanding resistance to corrosion even when the surfaces have suffered mechanical damage, for example by stone impact or scratching. A further advantage which is inherent with the method according to the present disclosure and with the application system according to the disclosure is that only very short changeover times are required in order to coat new substrate batches. Furthermore, the method according to the disclosure allows the scope of the entire system for manufacturing coated substrates, starting from the substrate which has not yet been cleaned and is to be coated, to be substantially reduced, such that a significantly reduced space is required in relation to conventional systems. In addition, it is possible with the methods according to the present disclosure to substantially reduce the processing time up to completion of the coated substrate ready for sale. Reduced cycle times are necessarily inherent with this.

The features disclosed in the foregoing description and in the claims can be essential for the implementation of the present disclosure in its different embodiments, both individually as well as in any combination. The various embodiments described above can be combined to provide further embodiments. All of the U.S. and foreign patent references referred to in this specification and/or listed in the Application Data Sheet are incorporated herein by reference, in their entirety. Aspects of the embodiments can be modified, if necessary to employ concepts of the various patent references to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method for manufacturing a coated non-metallic substrate, comprising:
a) providing a non-metallic substrate, with at least one surface which is capable of being coated at least in part areas,
b) providing an application system for the application of a metal layer,
c) providing at least one plasma generator and/or at least one corona system within the application system for the application of the metal layer, or as a component thereof,
d) as appropriate, providing plasma treatment with the plasma generator and/or corona treatment of the non-metallic substrate or of the coatable surface of the non-metallic substrate,
e) as appropriate, treating the non-metallic substrate, obtained according to step a) or d), or of the coatable surface of the non-metallic substrate, with at least one organosilicon compound by way of plasma polymerization, thus forming a polysiloxane layer,
f) as appropriate, providing plasma treatment with the plasma generator and/or corona treatment of the polysiloxane layer in accordance with step e),
g) as appropriate, applying at least one primer layer onto the non-metallic substrate, or onto the coatable surface of the non-metallic substrate, in accordance with step a) or d), or onto the polysiloxane layer in accordance with step e) or f),
h) as appropriate, providing plasma treatment with the plasma generator and/or corona treatment of the primer layer in accordance with step g),
i) as appropriate, treating the primer layer obtained according to step g) or h) with least one organosilicon compound by way of plasma polymerization, thus forming a polysiloxane layer,
j) as appropriate, providing plasma treatment with the plasma generator and/or corona treatment of the polysiloxane layer in accordance with step i),
k) applying at least one metal layer containing or consisting of a first metal selected from the group consisting of aluminum, silver, gold, lead, vanadium, manganese, magnesium, iron, cobalt, nickel, copper, chromium, palladium, molybdenum, tungsten, platinum, titanium, zirconium and zinc, or containing or consisting of a first metal alloy selected from the group consisting of brass, bronze, steel, and alloys of aluminum, magnesium and titanium, with the application system, onto the non-metallic substrate, or onto the coatable surface of the non-metallic substrate, in accordance with step a) or d), or onto the polysiloxane layer in accordance with step e) or f), or onto the primer layer in accordance with step g) or h), or onto the polysiloxane layer in accordance with step i) or j),
l) as appropriate, providing plasma treatment with the plasma generator and/or corona treatment of the metal layer in accordance with step k),
m) treating the metal layer obtained according to step k) or l) with at least one organosilicon compound by way of plasma polymerization, thus forming a polysiloxane layer,
n) providing plasma treatment with the plasma generator and/or corona treatment of the polysiloxane layer in accordance with step m), and
o) applying an overcoat, onto the treated polysiloxane layer in accordance with step n).

2. The method according to claim 1, wherein:
the steps g), h), k), m), n) and o) directly follow one another in each case, omitting the steps d), e) and/or f) or using step d) and omitting steps e) and f), or
the steps g), h), i), k), m), n) and o) directly follow one another in each case, omitting steps d), e) and/or f), or using step d) and omitting steps e) and f), or
the steps d), e), f), k), m), n) and o) directly follow one another in each case, or
the steps d), e), f), i), k), m), n) and o) directly follow one another, or
the steps d), e), f), g), k), m), n) and o) directly follow one another in each, or
the steps d), e), f), g), i), k), m), n) and o) directly follow one another in each case.

3. A method for manufacturing a coated metal substrate, comprising:
A) providing a metal substrate with at least one surface which is capable of being coated at least in part areas,
B) providing an application system for the application of a metal layer,
C) providing at least one plasma generator and/or at least one corona system within the application system for the application of the metal layer or as a component thereof,
D) as appropriate, cleaning the metal substrate or the coatable surface of the metal substrate,
E) as appropriate, applying at least one metal layer containing or consisting of a first metal selected from the group consisting of titanium, hafnium and zirconium, or of a first metal alloy selected from the group consisting of alloys of titanium, hafnium and zirconium, with the application system, onto the metal substrate or the coatable surface of the metal substrate in accordance with step A) or D),
F) as appropriate, providing plasma treatment with the plasma generator and/or corona treatment of the metal substrate or of the coatable surface of the metal substrate in accordance with step A) or D), or of the metal layer in accordance with step E),
G) as appropriate, treating the metal substrate obtained according to step A) or D), or treating the coatable surface of the metal substrate obtained according to step A) or D) or of the metal layer obtained according to step E) or F) with at least one organosilicon compound by way of plasma polymerization, thus forming a polysiloxane layer,
H) as appropriate, providing plasma treatment with the plasma generator and/or corona treatment of the polysiloxane layer in accordance with step G),
I) as appropriate, applying a conversion layer onto the metal substrate or the coatable surface of the metal substrate in accordance with step A) or D), or onto the metal layer in accordance with step E) or F), or onto the polysiloxane layer in accordance with step G) or H),
J) as appropriate, providing plasma treatment with the plasma generator and/or corona treatment of the conversion layer in accordance with step I),
K) as appropriate, treating the conversion layer obtained according to step I) or J) with at least one organosilicon compound by way of plasma polymerization, thus forming a polysiloxane layer,
L) as appropriate, providing plasma treatment with the plasma generator and/or corona treatment of the treated polysiloxane layer obtained according to step K),
M) as appropriate, applying at least one primer layer onto the metal substrate or the coatable surface of the metal substrate in accordance with step A) or D), or onto the metal layer in accordance with step E) or F), or onto the polysiloxane layer in accordance with step G) or H), or onto the conversion layer in accordance with step I) or J), or onto the polysiloxane layer in accordance with step K) or L),
N) as appropriate, providing plasma treatment with the plasma generator and/or corona treatment of the primer layer in accordance with step M),
O) as appropriate, treating the primer layer obtained according to step M) or N) with at least one organosilicon compound by way of plasma polymerization, thus forming a polysiloxane layer,
P) as appropriate, providing plasma treatment with the plasma generator and/or corona treatment of the treated polysiloxane layer obtained according to step O),
Q) applying at least one metal layer, containing or consisting of a second metal selected from the group consisting of aluminum, silver, gold, lead, vanadium, manganese, magnesium, iron, cobalt, molybdenum, tungsten, nickel, copper, chromium, palladium, platinum, titanium, zirconium and zinc, or containing or consisting of a second metal alloy selected from the group consisting of brass, bronze, steel, in particular special steel or stainless steel, alloys of aluminum, magnesium and titanium, with the application system, onto the metal substrate or the coatable surface of the metal substrate in accordance with step A) or D), or onto the metal layer in accordance with step E) or F), or onto the polysiloxane layer in accordance with step G) or H), or onto the conversion layer in accordance with step I) or J), or onto the polysiloxane layer in accordance with step K) or L), or onto the primer layer in accordance with step M) or N), or onto the polysiloxane layer in accordance with step O) or P),
R) as appropriate, providing plasma treatment with the plasma generator and/or corona treatment of the metal layer in accordance with step Q),
S) treating the metal layer obtained according to step Q) or R) with at least one organosilicon compound by way of plasma polymerization, thus forming a polysiloxane layer,
T) providing plasma treatment with the plasma generator and/or corona treatment of the polysiloxane layer in accordance with step S), and
U) applying an overcoat, onto the treated polysiloxane layer in accordance with step T).

4. The method according to claim 3, wherein:
the steps D), M), N), Q), S), T) and U) directly follow one another in each case, or
the steps D), M), N), O), Q), S), T) and U) directly follow one another in each case, or
the steps D), E), F), M), Q), S), T) and U) directly follow one another in each case, or
the steps D), E), F), M), O), Q), S), T) and U) directly follow one another in each case, or
the steps D), G), H), M), Q), S), T) and U) directly follow one another in each case, or
the steps D), G), H), M), O), Q), S), T) and U) directly follow one another in each case, or
the steps D), E), G), H), M), Q), S), T) and U) directly follow one another in each case, or
the steps D), E), G), H), M), O), Q), S), T) and U) directly follow one another in each case, or
the steps D), M), Q), S), T) and U) directly follow one another in each case, or
the steps D), M), O), Q), S), T) and U) directly follow one another in each case, or
the steps D), G), H), Q), S), T) and U) directly follow one another in each case, or
the steps D), G), H), O), Q), S), T) and U) directly follow one another in each case.

5. The method according to claim 1, wherein:
the metal substrate comprises metals or metal alloys, or consists of these, or the non-metallic substrate comprises glass, ceramics, fiber composite materials, carbon materials, plastic or wood, or consists of these.

6. The method according to claim 3, wherein:
the metal substrate is selected from the group consisting of aluminum, aluminum alloys, iron, iron alloys, copper, copper alloys, titanium, titanium alloys, zinc, zinc alloys, nickel, nickel alloys, molybdenum, molybdenum alloys, magnesium, magnesium alloys, lead, lead alloys, tungsten, tungsten alloys, manganese, manganese alloys, brass, bronze, die-cast nickel, die-cast zinc and die-cast aluminum, or any mixtures thereof.

7. The method according to claim 1, wherein:
the organosilicon compound comprises at least one amino-containing silane.

8. The method according to claim 1, wherein:
the provision of plasma treatment with the plasma generator is carried out:
using at least one inert gas, or
using at least one inert gas and oxygen, nitrogen, carbon dioxide, hydrogen, carbon monoxide, hydrogen peroxide gas, water vapor, ozone and/or air, or
using oxygen, nitrogen, hydrogen, carbon dioxide, carbon monoxide, hydrogen peroxide gas, water vapor, ozone and/or air.

9. The method according to claim 1, wherein:
the provision of plasma treatment with the plasma generator and/or the application of the metal layer and/or the application of the polysiloxane layer in the application system for the application of the metal layer is carried out in a vacuum vapor deposition system or in a sputtering system.

10. The method according to claim 1, wherein:
the overcoat comprises polyacrylate resins, polyester resins, amino resins or polyurethane compounds, or consists of these resins, and/or
the overcoat is formed from a UV-curing coating material or from a 1K or 2K stoving lacquer.

11. The method according to claim 1, wherein:
the metal layer is applied by way of Physical Vapor Deposition (PVD), Chemical Vapor Deposition (CVD), vapor deposition by way of an electron beam vapor depositor, vapor deposition by way of a resistance vapor depositor, induction vapor deposition, ARC vapor deposition, or cathode or anode atomization or sputter coating.

12. The method according to claim 3, wherein:
the cleaning of the metal substrate in accordance with step D) comprises degreasing, pickling, phosphating, polishing, grinding, and/or treating with dry ice.

13. The method according to claim 1, wherein:
in the step of the application of the metal layer, a first metal or a first metal alloy is co-vapor deposited overlapping in time with a second metal selected from the group consisting of titanium, zirconium and hafnium, or with a second metal alloy selected from the group consisting of alloys of titanium, zirconium and hafnium, in the application system for the application of the metal layer.

14. The method according to claim 1, wherein:
a first organosilicon compound is delivered to the application system, via a feed line from a first container located outside the application system for the application of the metal layer, and that a second organosilicon compound is delivered to the application system, via a feed line from a second container located outside the application system for the application of the metal layer.

15. The method according to claim 1, wherein:
at least one coloring agent, is introduced into the application system for the application of the metal layer together with the at least one organosilicon compound, and/or
a coating material which contains at least one coloring agent, is used for applying the overcoat.

16. The method according to claim 1, wherein:
the step of treatment with at least one organosilicon compound is carried out in the presence of at least one reactive gas.

17. The method according to claim 16, wherein:
the at least one organosilicon compound is hexamethyldisiloxane, and the at least one reactive gas is oxygen or air, and are used as a mixture for the treatment step.

18. The method according to claim 16, wherein:
the step of treatment with at least one organosilicon compound in the presence of at least one reactive gas is used at least for one step for the production of a polysiloxane layer or for each step for the production of a polysiloxane layer, in particular for step m) or for step S).

19. A non-metallic substrate, obtained according to a method in accordance with claim 1.

20. A metal substrate, obtained according to a method in accordance with claim 3.

21. An application system for the application of a metal layer in accordance with claim 1, comprising a vacuum vapor deposition system with a vacuum chamber and at least one first heatable reception unit or container, in each case operatively coupled with a first heating device, or comprising or representing a first heating device, in each case configured and suitable for receiving a first metal or a first metal alloy with a first melting point or melting range, and at least one second heatable reception unit, in each case operatively coupled with a second heating device, or comprising or representing a second heating device, in each case configured and suitable for receiving a second metal or a second metal alloy with a second melting point or melting range, wherein the first melting point or the first melting range is different from the second melting point or second melting range, and, in addition, a control device designed and configured for adjustment of first and second temperatures such that the first and second metal or the first and second metal alloys evaporate essentially simultaneously or overlapping in time.

22. The application system for the application of a metal layer according to claim 21, comprising:
at least one first container arranged outside the vacuum chamber of the vacuum vapor deposition system, for receiving a first organosilicon compound, with a feed line to the vacuum chamber, and at least one second container arranged outside the vacuum chamber of the vacuum vapor deposition system, for receiving a second organosilicon compound, with a feed line to the vacuum chamber.

23. The application system for the application of a metal layer according to claim 21, further comprising:
at least one frame arranged within the vacuum chamber, with a longitudinal orientation and with at least one support in the form of a shaft, which is aligned essentially along the longitudinal orientation of the frame, designed and configured to receive at least one, non-metallic and/or metallic substrate, wherein the frame and/or the at least one support is/are capable of being rotated about an axis aligned essentially vertically or horizontally.

24. A method of using a non-metallic substrate obtained in accordance with claim 1, as an accessory for automobile manufacture, motorcycle manufacture, bicycle manufacture or shipbuilding, for rims, or as a constituent part thereof, for sanitary installation objects or as a constituent part thereof, for automobile body internal or external components or as a constituent part thereof, for handles or handle components or as a constituent part thereof, for profiles or frames or as a constituent part thereof, for fittings systems or as a constituent part thereof, for housings or as packing or as a constituent part thereof, for internal or external components of ships or as a constituent part thereof, for domestic appliances or as a constituent part thereof, for jewelry items or as a constituent part thereof, for high-quality structural components or as a constituent part thereof, for indoor or outdoor furniture items or for constituent parts thereof, for internal or external components of aircraft or as a constituent part thereof, for internal or external components of buildings or as a constituent part thereof, for heating elements or pipes or as a constituent part thereof, for elevator components or as a constituent part thereof, for parts of electronic components or devices or as a constituent part thereof, for components of kitchen appliances, or as a part of communications components or devices or as a constituent part thereof.

25. A method of using a metal substrate obtained in accordance with claim 3, as an accessory for automobile manufacture, motorcycle manufacture, bicycle manufacture or shipbuilding, for rims, wheels or as a constituent part thereof, for sanitary installation objects or as a constituent part thereof, for automobile body internal or external components or as a constituent part thereof, for handles or handle components or as a constituent part thereof, for profiles or frames or as a constituent part thereof, for fittings systems or as a constituent part thereof, for housings or as packing or as a constituent part thereof, for internal or external components of ships or as a constituent part thereof, for domestic appliances or as a constituent part thereof, for jewelry items or as a constituent part thereof, for high-quality structural components or as a constituent part thereof, for indoor or outdoor furniture items or for constituent parts thereof, for internal or external components of aircraft or as a constituent part thereof, for internal or external components of buildings or as a constituent part thereof, for heating elements or pipes or as a constituent part thereof, for elevator components or as a constituent part thereof, for parts of electronic components or devices or as a constituent part thereof, for components of kitchen appliances, or as a part of communications components or devices or as a constituent part thereof.

26. The method according to claim 3, wherein:
the metal substrate comprises metals or metal alloys, or consists of these, or the non-metallic substrate comprises glass, ceramics, fiber composite materials, carbon materials, plastic or wood, or consists of these.

27. The method according to claim 3, wherein:
the organosilicon compound comprises at least one amino-containing silane.

28. The method according to claim 3, wherein:
the provision of plasma treatment with the plasma generator is carried out:
using at least one inert gas, or
using at least one inert gas and oxygen, nitrogen, carbon dioxide, hydrogen, carbon monoxide, hydrogen peroxide gas, water vapor, ozone and/or air, or
using oxygen, nitrogen, hydrogen, carbon dioxide, carbon monoxide, hydrogen peroxide gas, water vapor, ozone and/or air.

29. The method according to claim 3, wherein:
the provision of plasma treatment with the plasma generator and/or the application of the metal layer and/or the application of the polysiloxane layer in the application system for the application of the metal layer is carried out in a vacuum vapor deposition system or in a sputtering system.

30. The method according to claim 3, wherein:
the overcoat comprises polyacrylate resins, polyester resins, amino resins or polyurethane compounds, or consists of these resins, and/or
the overcoat is formed from a UV-curing coating material or from a 1K or 2K stoving lacquer.

31. The method according to claim 3, wherein:
the metal layer is applied by way of Physical Vapor Deposition (PVD), Chemical Vapor Deposition (CVD), vapor deposition by way of an electron beam vapor depositor, vapor deposition by way of a resistance vapor depositor, induction vapor deposition, ARC vapor deposition, or cathode or anode atomization or sputter coating.

32. The method according to claim 3, wherein:
in the step of the application of the metal layer, a first metal or a first metal alloy is co-vapor deposited overlapping in time with a second metal selected from the group consisting of titanium, zirconium and hafnium, or with a second metal alloy selected from the group consisting of alloys of titanium, zirconium and hafnium, in the application system for the application of the metal layer.

33. The method according to claim 3, wherein:
a first organosilicon compound is delivered to the application system, via a feed line from a first container located outside the application system for the application of the metal layer, and that a second organosilicon compound is delivered to the application system, via a feed line from a second container located outside the application system for the application of the metal layer.

34. The method according to claim 3, wherein:
at least one coloring agent, is introduced into the application system for the application of the metal layer together with the at least one organosilicon compound, and/or
a coating material which contains at least one coloring agent, is used for applying the overcoat.

35. The method according to claim 3, wherein:
the step of treatment with at least one organosilicon compound is carried out in the presence of at least one reactive gas.

36. The method according to claim 35, wherein:
the at least one organosilicon compound is hexamethyldisiloxane, and the at least one reactive gas is oxygen or air, and are used as a mixture for the treatment step.

37. The method according to claim 35, wherein:
the step of treatment with at least one organosilicon compound in the presence of at least one reactive gas is used at least for one step for the production of a polysiloxane layer or for each step for the production of a polysiloxane layer, in particular for step m) or for step S).

38. An application system for the application of a metal layer in accordance with claim 3, comprising a vacuum vapor deposition system with a vacuum chamber and at least one first heatable reception unit or container, in each case operatively coupled with a first heating device, or comprising or representing a first heating device, in each case configured and suitable for receiving a first metal or a first metal alloy with a first melting point or melting range, and at least one second heatable reception unit, in each case operatively coupled with a second heating device, or comprising or representing a second heating device, in each case configured and suitable for receiving a second metal or a second metal alloy with a second melting point or melting range, wherein the first melting point or the first melting range is different from the second melting point or second melting range, and, in addition, a control device designed and configured for adjustment of first and second temperatures such the first and second metal or the first and second metal alloys evaporate essentially simultaneously or overlapping in time.

39. The application system for the application of a metal layer according to claim 38, comprising:
at least one first container arranged outside the vacuum chamber of the vacuum vapor deposition system, for receiving a first organosilicon compound, with a feed line to the vacuum chamber, and at least one second container arranged outside the vacuum chamber of the vacuum vapor deposition system, for receiving a second organosilicon compound, with a feed line to the vacuum chamber.

40. The application system for the application of a metal layer according to claim 38, further comprising:
at least one frame arranged within the vacuum chamber, with a longitudinal orientation and with at least one support in the form of a shaft, which is aligned essentially along the longitudinal orientation of the frame, designed and configured to receive at least one, non-metallic and/or metallic substrate, wherein the frame and/or the at least one support is/are capable of being rotated about an axis aligned essentially vertically or horizontally.
